(19) United States
(12) Patent Application Publication
(10) Pub. No.: US 2007/0018727 A1
(43) Pub. Date: Jan. 25, 2007

(54) Variable gain amplifier and wireless communication apparatus including the same

(75) Inventors: Jeong-ho Lee, Suwon-si (KR); Hyun-koo Kang, Yongin-si (KR); Dae-yeon Kim, Suwon-si (KR); Jae-young Ryu, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/483,069

(22) Filed: Jul. 10, 2006

(30) Foreign Application Priority Data
Jul. 8, 2005 (KR) 10-2005-0061839

(51) Int. Cl. H03F 3/45

(52) U.S. Cl. 330/254

(57) ABSTRACT

Disclosed is a variable gain amplifier. The variable gain amplifier includes a gain control unit to transmit input differential signals as they are when it operates in a high gain mode, and to transmit the signals by way of predetermined impedances when operating in a low gain mode, and an amplification unit to amplify the input differential signals output from the gain control unit.

### CROSS-REFERENCE TO RELATED APPLICATION

This application claims priority from Korean Patent Application No. 10-2005-0061839 filed on Jul. 8, 2005 in the Korean Intellectual Property Office, the disclosure of which is incorporated herein by reference in its entirety.

### BACKGROUND OF THE INVENTION

1. Field of the Invention

Devices consistent with the present invention are directed to variable gain amplifiers. More particularly, the present invention relates to a variable gain amplifier and a wireless communication apparatus including the same, having stable input/output matching characteristics.

2. Description of the Related Art

Generally, when a wireless communication apparatus transmits or receives a signal, a variable gain amplifier is necessary, to thereby constantly maintain the power of the signal output through an antenna, or to maintain a proper gain of the signal received via the antenna.

The basic structure of a high frequency amplifier comprises a common source, a common gate and a common collector. However, a cascade structure is generally used, in which the common source and the common gate are combined in two stages, and only the current of one of them is used, and an effect of gain and input/output isolation occurs.

As a gain control method of the variable gain amplifier, the gains are conventionally controlled by controlling the load impedance. FIG. 1 illustrates a circuit diagram according to this conventional control method.

Referring to FIG. 1, nodes “a” and “b” represent differential input ports of the amplifier, and node “c” is connected to an AC/DC ground. Transistors “M1” and “M2” are MOSFET transistors that operate as the common source, and transistors “M3” and “M4” are MOSFET transistors that operate as the common gate. Node “d” is connected to an AC ground.

Nodes “e” and “f” are differential output ports of the amplifier, and elements “E1” and “E2” are load impedances of the amplifier.

Elements “E3” and “E4” are resistors for adjusting the gains of the amplifier, and “S1” and “S2” are switches to adjust the gains of the amplifier, which can be embodied by a MOSFET transistor in a general manner.

In the load impedance control method illustrated in FIG. 1, gains of the amplifier may be adjusted by changing the output resistance of the load by use of the switches “S1” and “S2” and the resistors “E3” and “E4.”

That is, this method is to adjust the gains by changing R_{Load} at the gain of G=gₘ R_{Load}.

For example, when the switches “S1” and “S2” are on, the value of R_{Load} becomes small, thereby producing a low gain. Conversely, when the switches “S1” and “S2” are off, the switches “S1” and “S2” are open and the value of R_{Load} becomes relatively large, thereby producing a high gain.

In the method illustrated in FIG. 1, if a high gain state, in which the output impedance is matched at 50 Ω, is changed to a low gain state, the output impedance will necessarily have a value smaller than 50 Ω, thereby producing an impedance mismatch. In contrast, when a low gain state, in which the output impedance is matched at 50 Ω, is changed to a high gain state, the output impedance has a value larger than 50 Ω, thereby causing a problem in delivering power. In addition, since this structure changes the value of R_{Load}, there is a limit in changing gains, and it is difficult to have a dynamic range over 10 dB. In the low gain mode, the output 1 dB compression point (P1dB) and the output 3^{rd} order intercept point (OIP3) are decreased. To solve these problems, a one-stage amplifier may be used; in this case, since a large amount of current is consumed, it is not appropriate for low current devices, such as mobile devices.

Accordingly, in order to solve these problems the high frequency amplifier needs to be designed so that a stable adjustment of gains is possible.

### SUMMARY OF THE INVENTION

An aspect of the present invention is to provide a high frequency amplifier capable of conducting stable adjustment of gains and a wireless communication apparatus including the same.

Another aspect of the present invention is to resultantly maintain an output 1 dB compression point and an output 3^{rd} order intercept point by enlarging an input 1 dB compression point and an input 3^{rd} order intercept point when the high frequency amplifier operates at a low gain state.

A further aspect of the present invention is to stabilize input/output impedances of the high frequency amplifier without regard to gain control.

The present invention will not be limited to the technical aspects described above. Other aspects not described herein will be more definitely comprehended by those in the art from the following detailed description.

According to an aspect of the present invention, there is provided a variable gain amplifier comprising a gain control unit to transmit input differential signals as they are when it operates in a high gain mode, and to transmit the signals by way of predetermined impedances when operating in a low gain mode, and an amplification unit to amplify the input differential signals output from the gain control unit.

According to another aspect of the present invention, there is provided a wireless communication apparatus comprising a variable gain amplifier comprising a gain control unit to transmit input differential signals as they are when it operates in a high gain mode, and to transmit the signals by way of predetermined impedances when operating in a low gain mode, and an amplification unit to amplify the input differential signals output from the gain control unit, and an antenna to wirelessly output in a channel RF signals amplified by the variable gain amplifier.

According to a further aspect of the present invention there is provided a wireless communication apparatus comprising an antenna to receive RF signals from a wireless channel, and a variable gain amplifier comprising a gain control unit to transmit input differential signals as they are when it operates in a high gain mode, and to transmit the signals by way of predetermined impedances when it operates in a low gain mode, and an amplification unit to amplify the input differential signals output from the gain control unit.

### BRIEF DESCRIPTION OF THE DRAWINGS

The above and other features and advantages of the present invention will become more apparent by describing in detail preferred embodiments thereof with reference to the attached drawings in which:

FIG. 1 is a circuit diagram for illustrating a conventional gain control method of a high frequency amplifier by controlling load impedance;

FIG. 2 is a block diagram illustrating a wireless communication apparatus comprising a variable gain amplifier according to an exemplary embodiment of the present invention;

FIG. 3 is a circuit diagram illustrating a variable gain amplifier according to an exemplary embodiment of the present invention;

FIGS. 4A and 4B illustrate equivalent circuits of the gain control unit of FIG. 3;

FIG. 5 shows graphs illustrating input/output impedance matching according to an exemplary embodiment of the present invention;

FIG. 6 shows graphs illustrating the relation between an input IdB compression point and gains according to an exemplary embodiment of the present invention; and

FIG. 7 shows graphs illustrating the relation between an input 3^{rd} order intercept point and gains according to an exemplary embodiment of the present invention.

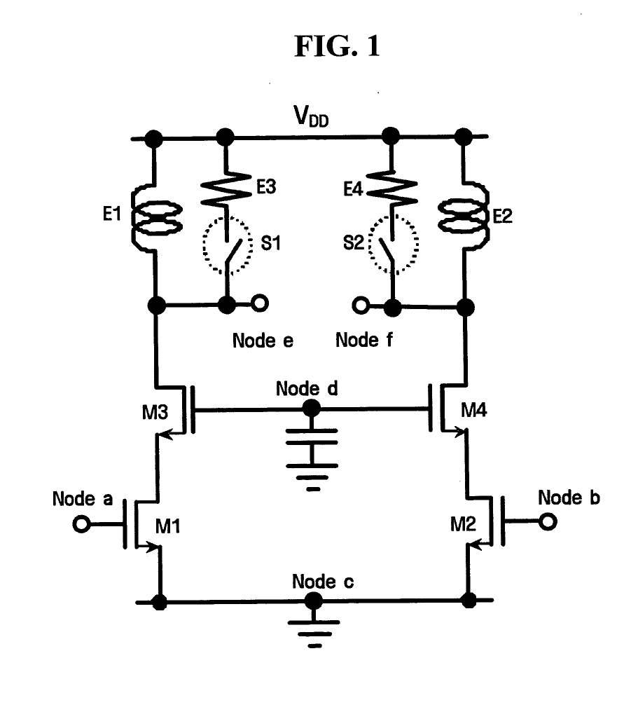

### DETAILED DESCRIPTION OF THE INVENTION

The present invention will now be described more fully with reference to the accompanying drawings, in which exemplary embodiments of the invention are shown. Advantages and features of the present invention and methods of accomplishing the same may be understood more readily by reference to the following detailed description of exemplary embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims.

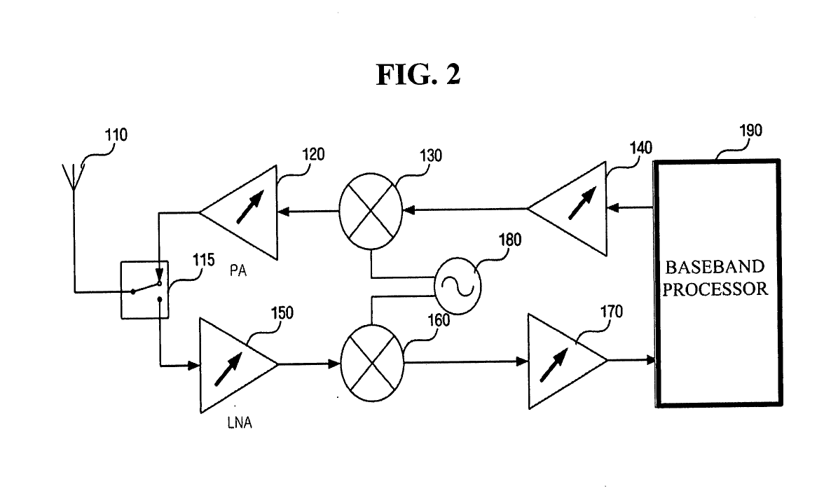

FIG. 2 is a block diagram illustrating a wireless communication apparatus comprising a variable gain amplifier according to an exemplary embodiment of the present invention.

Operations of the wireless communication apparatus will be described in terms of the transmission process.

A baseband signal output from a baseband processor 190 is amplified by a baseband amplifier 140. The amplified baseband signal is mixed with an oscillation signal generated by an oscillator 180 in an up mixer 130, to thereby produce a radio frequency (RF) signal. Most conventional communication systems do not directly convert the baseband signal into the RF signal; they first convert it into an intermediate frequency (IF) signal and then convert the IF signal into an RF signal. The RF signal is amplified by a power amplifier 120 and then wirelessly output in a channel through an antenna 110.

The power amplifier 120 used in the transmission process may be constructed of a multi-stage amplifier to obtain a high gain with low distortion. For example, the wireless communication apparatus may comprise a preamplifier and a power amplifier. The power amplifier 120 comprises a gain control unit and an amplification unit according to an exemplary embodiment of the present invention, wherein gains of the amplification unit are controlled by the gain control unit.

Operations of the wireless communication apparatus will be described in terms of the reception process.

An RF signal input via a wireless channel through an antenna 110 is amplified by way of a low noise amplifier 150. The low noise amplifier 150 comprises a gain control unit and an amplification unit according to an exemplary embodiment of the present invention, wherein gains of the amplification unit are controlled by the gain control unit.

The amplified RF signal is converted to a baseband signal by way of a down mixer 160 and is amplified by the baseband amplifier 170. Most communication systems currently known do not directly convert the RF signal into the baseband signal; they first convert it into an intermediate frequency (IF) signal and then the converted IF signal is converted into the baseband signal. The amplified baseband signal is then transferred to the baseband processor 190. The low noise amplifier 150 may also be constructed of multi-stage amplifiers to obtain sufficient gains.

The switch 115 intercepts input of the RF signal output from the power amplifier 120, and transfers to the power amplifier 120 the RF signal received via the antenna 110. In the full duplex-type communication system, a duplexer may be used instead of the switch 115.

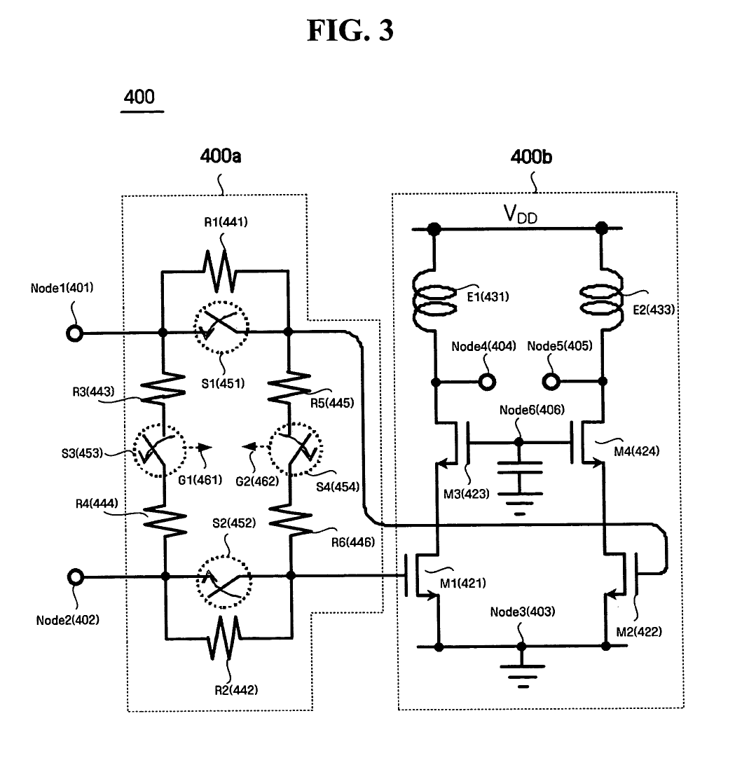

FIG. 3 is a circuit diagram illustrating a variable gain amplifier according to an exemplary embodiment of the present invention. The variable gain amplifier 400 may be a power amplifier 120 or the low noise amplifier 150 depicted in FIG. 2.

The variable gain amplifier 400 may be composed of a gain control unit 400a and an amplification unit 400b. The amplification unit 400b has the structure of a differential cascade amplifier, to thereby control gains of the amplification unit 400b by positioning the gain control unit 400a in the front stage of the amplification unit 400b.

Node 1 401 and node 2 402 represent differential input ports of the variable gain amplifier 400, and node 3 403 is connected to DC and AC grounds.

Node 4 404 and node 5 405 represent differential output ports of the variable gain amplifier 400, and node 6 406 is connected to the AC ground through a capacitor.

Resistors R1 441 and R2 442 of the gain control unit 400a operate in a low gain mode, and form a serial path relative to an input terminal of the amplification unit 400b.

Resistors R3 443, R5 445, R4 444 and R6 446 of the gain control unit 400a operate in a low gain mode, and form a parallel path relative to an input terminal of the amplification unit 400b.

Switches S1 451 and S2 452 of the gain control unit 400a are on in a high gain mode, but off in a low gain mode. Switches S1 451 and S2 452 may be implemented by use of a field effect transistor (FET) or a bipolar junction transistor (BJT).

Switches S3 453 and S4 454 of the gain control unit 400a are off in a high gain mode, but on in a low gain mode. Likewise, switches S3 453 and S4 454 may be implemented by use of a metal oxide semiconductor field effect transistor (MOSFET) or a BJT.

G1 461 and G2 462 represent virtual grounds according to a differential structure of the variable gain amplifier 400.

Transistors M1 421 and M2 422 represent n-channel metal oxide semiconductor (NMOS) transistors that operate with a common source, transistors M3 423 and M4 424 represent NMOS transistors that operate with a common gate.

Node 4 404 and node 5 405 represent differential output ports of the variable gain amplifier 400, and elements E1 431 and E2 433 represent load impedances of the variable gain amplifier 400.

The case where the gain control unit 400a operates in a high gain mode will be described.

In this case, switches SI 451 and S2 452 are on, and switches S3 453 and S4 454 are off.

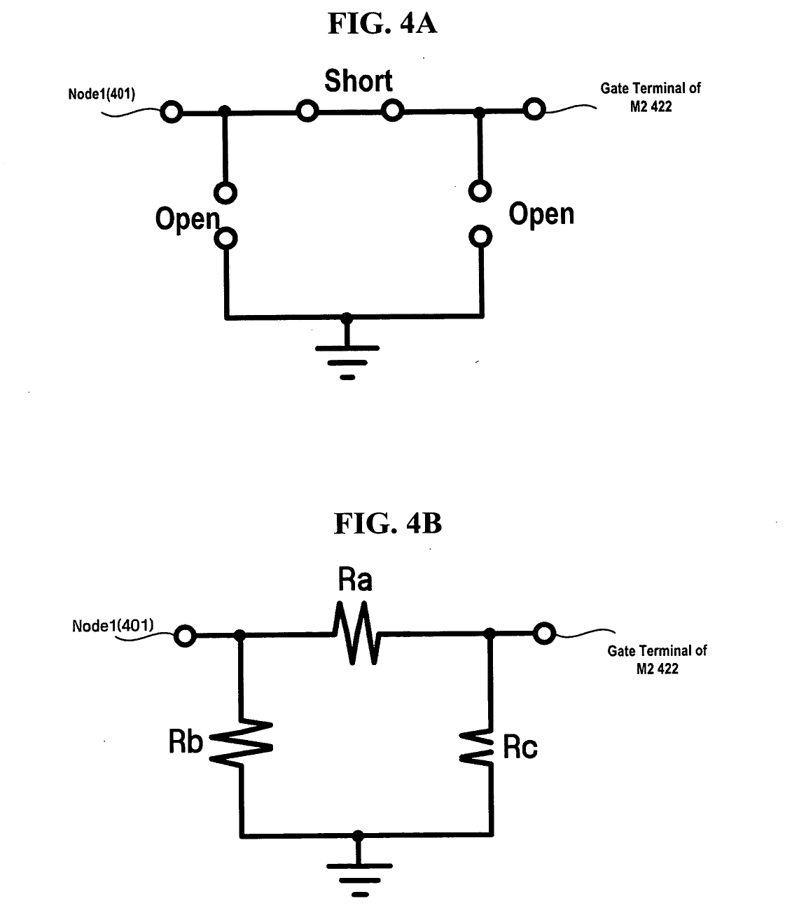

And the gain control unit 400a operates as an equivalent circuit to that depicted in FIG. 4A.

Node 1 401 and the gate terminal of transistor M2 422 are shorted, and they are open against virtual grounds G1 461 and G2 462. Accordingly, when the gain control unit 400a operates in a high gain mode, the high frequency signal input into the node 1 401 is transmitted as it is to the gate terminal of the transistor M2 422, which constitutes an input terminal of the amplification unit 400b. Thus, the loss is OdB, and input/output impedance matching represents properties of the amplification unit 400b.

The equivalent circuit depicted in FIG. 4A can be applied in the same manner between node 2 402 and transistor M1 421.

The case where the gain control unit 400a operates in a low gain mode will be described.

In this case, switches S1 451 and S2 452 are off and switches S3 453 and S4 454 are on.

And the gain control unit 400a operates as an equivalent circuit to that depicted in FIG. 4B.

Resistor Ra is serially positioned between node 1 401 and the gate terminal of transistor M2 422, and resistors Rb and Rc are respectively connected to the virtual grounds G1 461 and G2 462, whereby they are positioned in parallel against node 1 401 and transistor M2 422. Here, resistances Ra, Rb and Rc respectively correspond to R1 441, R3 443 and R5 445 of FIG. 3.

The loss L, the matching impedance Zo, and resistances Ra, Rb and Rc in the equivalent circuit depicted in FIG. 4b can be expressed as follows.

$$Ra = \frac{Zo}{2} \times ( {10}^{\frac{L}{10}} - 1 ) \times ( {10}^{- \frac{L}{20}} )$$

$$Rb = Rc = \frac{1}{\frac{{10}^{\frac{L}{10}} + 1}{Zo \times ( {10}^{\frac{L}{10}} - 1 )} - \frac{1}{Ra}}$$

In an equivalent circuit illustrated in FIG. 4, Rb and Rc are symmetrical and, thus, have the same value. In addition, assuming that one side of the equivalent circuit represents input and the other side represents output, values for Ra, Rb, and Rc can be obtained when solving for L from S21=−L (Loss). These steps may be easily understood by those of ordinary skill in the art.

The values of “L” and “Zo” may vary according to the devices used, but they are constants for each device.

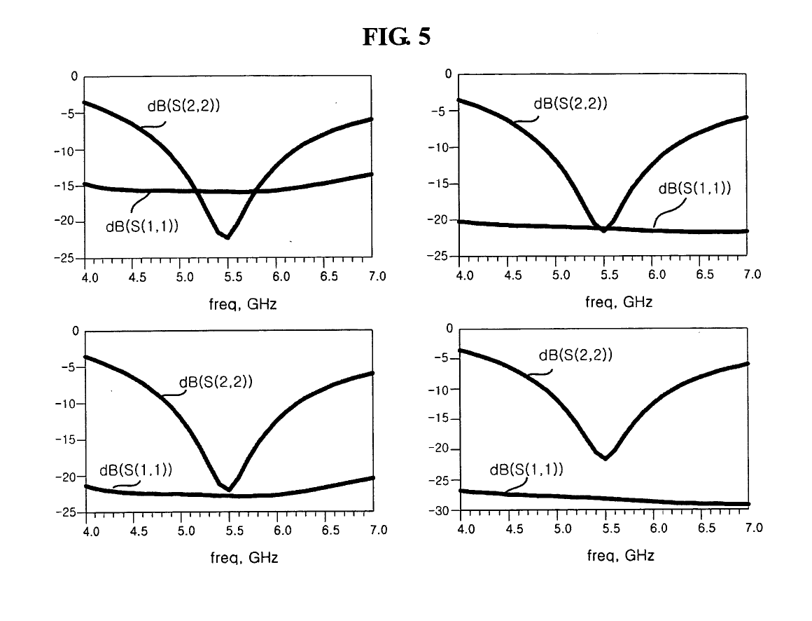

FIG. 5 shows graphs illustrating input/output impedance matching according to an exemplary embodiment of the present invention; FIG. 5 shows that the impedance matching characteristic relative to input and output is excellent across the overall band. dB (1, 1) denotes input impedance matching and dB (2, 2) denotes output impedance matching. Each graph illustrated in FIG. 5 denotes resultant input/output matching according to change in gain. Despite the change in gain, it is apparent that input impedance matching and output impedance matching sufficiently match with each other within a range of −10 dB.

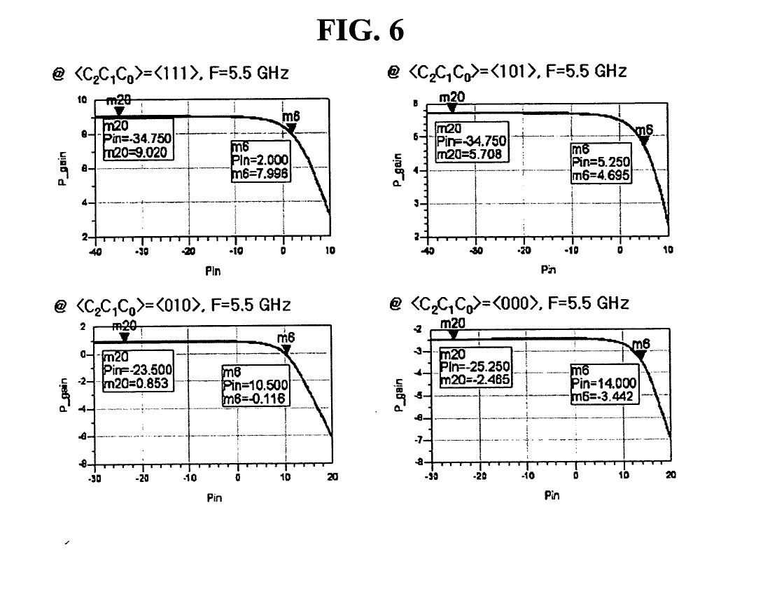

FIG. 6 shows graphs illustrating relations between an input 1 dB compression point and a gain according to an exemplary embodiment of the present invention; FIG. 6 shows the relationship of the input 1 dB compression point and gains according to gain control.

Referring to FIG. 6, since the input 1 dB compression point increases as gains decrease, the output 1 dB compression point is not affected by the gains.

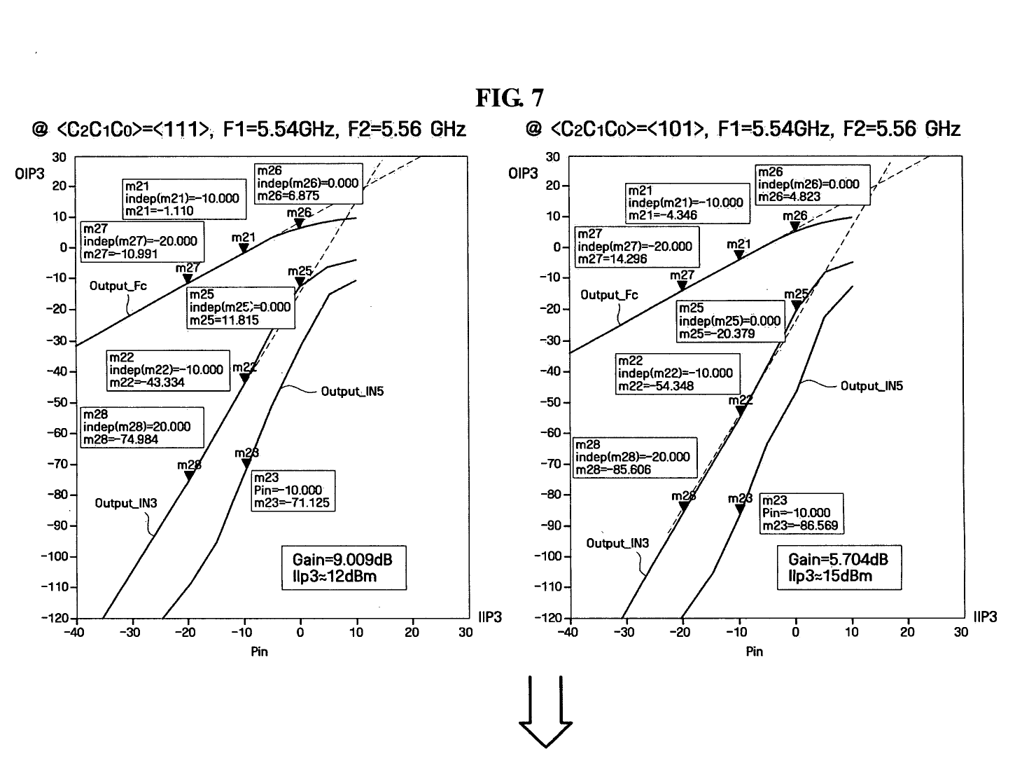

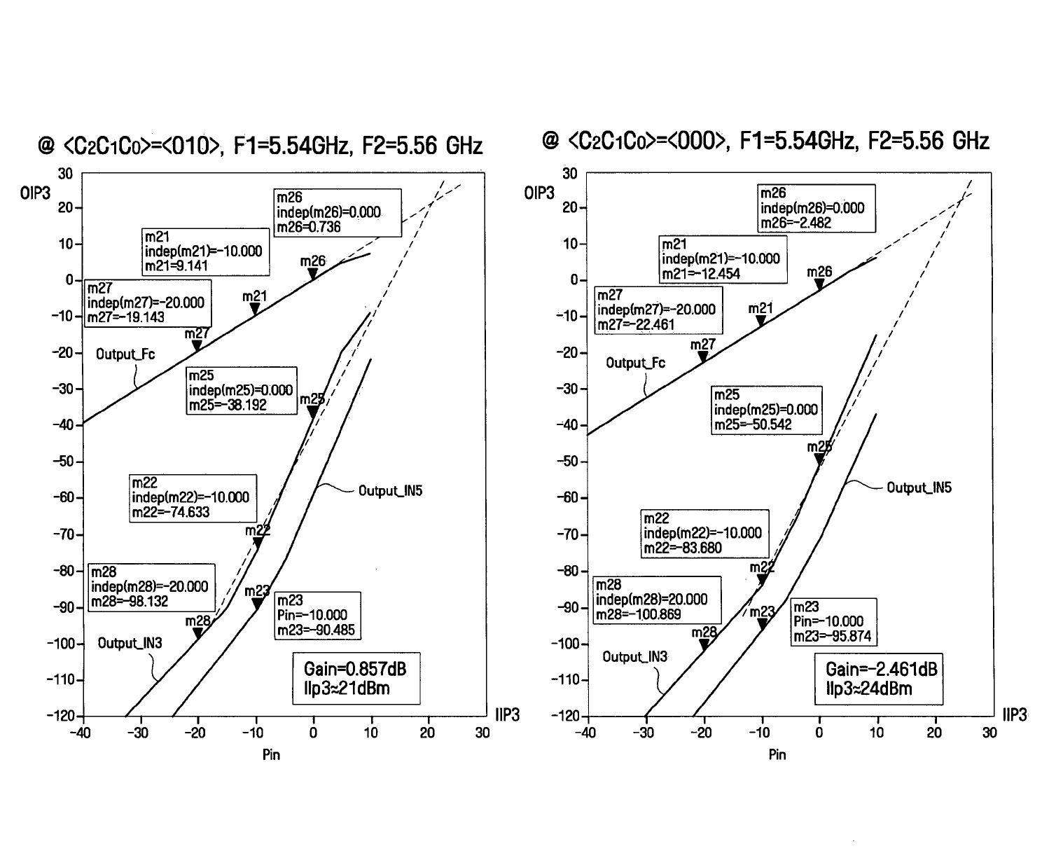

FIG. 7 shows graphs illustrating relations between an input 3^{rd} order intercept point and gains according to an exemplary embodiment of the present invention; FIG. 7 shows characteristics of the input 3^{rd} order intercept point and harmonic distortion of the high frequency according to gain control.

Referring to FIG. 7, since the input 3rd order intercept point (IIP3) increases as gains decrease, the output 3rd order intercept point (OIP3) is not affected by the gains.

According to the present invention, a variable gain amplifier is achieved that enables gain control without distorting input/output impedance matching, and it is effective in preventing the output 1 dB compression point and the output 3rd order intercept point from being reduced at the time of gain control.

Although the present invention has been described in connection with the exemplary embodiments of the present invention, it will be apparent to those skilled in the art that various modifications and changes may be made thereto without departing from the scope and spirit of the invention. Therefore, it should be understood that the above embodiments are not limitative, but illustrative in all aspects.

What is claimed is:

1. A variable gain amplifier comprising:
a gain control unit configured to selectively transmit input differential signals unchanged when the variable gain amplifier operates in a high gain mode, and transmit the signals by way of predetermined impedances when the variable gain amplifier operates in a low gain mode; and
an amplification unit to amplify the input differential signals output from the gain control unit.

2. The variable gain amplifier of claim 1, wherein the impedances are resistors.

3. The variable gain amplifier of claim 1, wherein a serial path, on which a first impedance is positioned, is formed between an input terminal and an output terminal of the gain control unit, and a parallel path, on which a second impedance is positioned, is formed between the input terminal and the output terminal of the gain control unit.

4. The variable gain amplifier of claim 1, wherein the amplification unit has a differential cascade structure, and amplifies differential signals input from the gain control unit.

5. A wireless communication apparatus comprising:
a variable gain amplifier comprising a gain control unit configured to selectively transmit input differential signals unchanged when the variable gain amplifier operates in a high gain mode, and transmit the signals by way of predetermined impedances when the variable gain amplifier operates in a low gain mode, and an amplification unit to amplify the input differential signals output from the gain control unit; and
an antenna to wirelessly output in a channel RF signals amplified by the variable gain amplifier.

6. The wireless communication apparatus of claim 5, wherein the impedances are resistors.

7. The wireless communication apparatus of claim 5, wherein a serial path, on which a first impedance is positioned, is formed between an input terminal and an output terminal of the gain control unit, and a parallel path, on which a second impedance is positioned, is formed between the input terminal and the output terminal of the gain control unit.

8. The wireless communication apparatus of claim 5, wherein the amplification unit is formed of a differential cascade structure that amplifies differential signals input from the gain control unit.

9. A wireless communication apparatus comprising:
an antenna to receive RF signals from a wireless channel; and
a variable gain amplifier comprising a gain control unit configured to selectively transmit input differential signals unchanged when the variable gain amplifier operates in a high gain mode, and transmit the signals by way of predetermined impedances when the variable gain amplifier operates in a low gain mode, and an amplification unit to amplify the input differential signals output from the gain control unit.

10. The wireless communication apparatus of claim 9, wherein the impedances are resistors.

11. The wireless communication apparatus of claim 9, wherein a serial path, on which a first impedance is positioned, is formed between an input terminal and an output terminal of the gain control unit, and a parallel path, on which a second impedance is positioned, is formed between the input terminal and the output terminal of the gain control unit.

12. The wireless communication apparatus of claim 9, wherein the amplification unit has a differential cascade structure, and amplifies differential signals input from the gain control unit.
